(19) United States
(12) Patent Application Publication
(10) Pub. No.: US 2016/0299180 A1
(43) Pub. Date: Oct. 13, 2016

(54) SOLAR PHOTOVOLTAIC GENERATION MONITORING SYSTEM AND METHOD FOR MONITORING SOLAR PHOTOVOLTAIC GENERATION

(71) Applicant: National Taiwan University, Taipei (TW)

(72) Inventors: Min-Sheng Liao, Taipei (TW); Joe-Air Jiang, Taipei (TW); Kun-Chang Kuo, Taipei (TW); Te-Hao Chang, Taipei (TW); Po-Han Chen, Taipei (TW); Tsang-Cheng Lin, Taipei (US); Cheng-Yue Liu, Taipei (TW)

(21) Appl. No.: 15/095,423

(22) Filed: Apr. 11, 2016

Related U.S. Application Data
(60) Provisional application No. 62/145,865, filed on Apr. 10, 2015.

(30) Foreign Application Priority Data
Oct. 15, 2015 (TW) 104133834

(51) Int. Cl. G01R 22/06; G01R 21/06; H02S 50/00; G01W 1/02

(52) U.S. Cl. CPC G01R 22/063; G01W 1/02; G01R 21/06; H02S 50/00

(57) ABSTRACT

The present disclosure provides a solar photovoltaic generation monitoring system and a method for monitoring solar photovoltaic generation. The system collects electrical and environmental parameters of a plurality of solar photovoltaic generation devices by using a plurality of sensor devices. The electrical and environmental parameters are transmitted into a server through a plurality of wireless communication device and a gateway. Therefore, the present disclosure can overcome the problems of high costs and the difficulties of hard wire deployment, and thus has advantages such as easy repair and low costs.

### CROSS-REFERENCE TO RELATED APPLICATION

The present application is based on and claims priority from Taiwan Application Number 104133834, filed Mar. 14, 2016 and claims benefit from U.S. Provisional Application No. 62/145,865, filed Apr. 10, 2015, the disclosure of which is hereby incorporated by reference herein in its entirety.

### BACKGROUND

1. Technical Field

The present disclosure relates to a monitoring technique, and particularly a solar photovoltaic generation monitoring system and method for monitoring solar photovoltaic generation based on wireless detection network.

2. Description of the Related Art

To reduce the negative impact on nature environment caused by global warming, the governments of many countries in the world have already initiated many renewable energy projects. Among these projects, solar photovoltaic generation might be the most popular selection.

Taiwan is a narrow island state, and the location of Taiwan is between tropical and subtropical region. Therefore, the amount of solar insolation is sufficient, and that provides an advantaged environment for developing solar energy. In order to understand the relationship between the level of solar insolation and the generated power, the generated power is calculated by measuring voltage and current of solar cell, and so far, the measured parameters, such as voltage and current, are still transmitted via wired network to back-end platform. In addition, to achieve the maximum power generation efficiency, a plurality of solar photovoltaic generation devices will be provided scatteredly on several regions having sufficient insolation. However, it is high cost and hard to deploy because the area is too broad. Moreover, more monitoring spots means the design of router of wired network will be more complicate and hard to maintain. Accordingly, the cost on time and money for repair will inevitably raise.

From the foregoing, how to provide a solar photovoltaic generation monitoring system and method thereof is one of the most urgent issues so far.

### SUMMARY

To solve the aforementioned problems, the present disclosure provides a solar photovoltaic generation monitoring system, including: a plurality of sensor devices, each provided in a plurality of solar photovoltaic generation devices for acquiring electrical parameters of the plurality of solar photovoltaic generation devices and environmental parameters around the plurality of solar photovoltaic generation devices; a plurality of wireless communication devices, each connected to the plurality of sensor devices for receiving the electrical parameters and the environmental parameters; a gateway disposed in a wireless communication range corresponding to the plurality of wireless communication devices for receiving the electrical parameters and the environmental parameters; and a server connected to the gateway for receiving the electrical parameters and the environmental parameters from the gateway and storing the electrical parameters and the environmental parameters in the server.

The present disclosure also provides a method for monitoring solar photovoltaic generation, comprising: broadcasting network deployment packets to a plurality of communication devices to ensure whether a gateway is provided within a wireless communication range corresponding to the plurality of communication devices and ensure the number of the wireless communication devices connecting to the gateway; providing to the gateway an acknowledgement packet of the plurality of wireless communication devices receiving the network deployment packet to build connection between the gateway and the plurality of wireless communication devices; transmitting, by the gateway, inquiry packets to the plurality of wireless communication devices with the built connection for the plurality of wireless communication devices to transmit electrical parameters of a plurality of solar photovoltaic generation devices and environmental parameters around the plurality of solar photovoltaic generation devices to the gateway; and transmitting, by the gateway, the electrical parameters and the environmental parameters to a server, and storing the electrical parameters and the environmental parameters to the server.

The solar photovoltaic generation monitoring system and method for monitoring solar photovoltaic generation use wireless sensing network assembled by a plurality of wireless communication devices and a gateway to solve the problem of high cost and the difficulties for building a monitoring system with wired network, thereby providing a stable system and monitoring technique. Since the solar photovoltaic generation efficiency is affects by not only the amount of insolation, but also other climate factors, the solar photovoltaic generation monitoring system and method for monitoring solar photovoltaic generation according to the present disclosure can immediately collect electrical parameters and environmental parameters, and continuously transmit to a database of a back-end server, thereby providing a user to browse the work condition and generation quality via Internet in real time.

### BRIEF DESCRIPTION OF THE DRAWINGS

FIG. 1 is a schematic diagram of the solar photovoltaic generation monitoring system according to the present disclosure; and

FIG. 2 is a flow chart of the method for monitoring solar photovoltaic generation according to the present disclosure.

### DETAILED DESCRIPTIONS

The following specific embodiments are provided to illustrate the disclosure of the present disclosure in detail, a person having ordinary skill in the art can easily understand the advantages and effects of the present disclosure after reading the disclosure of this specification, and also can implement or apply in other different specific embodiments. Therefore, any element or method within the scope of the present disclosure disclosed herein can combine with any other element or method disclosed in any specific embodiment of the present disclosure.

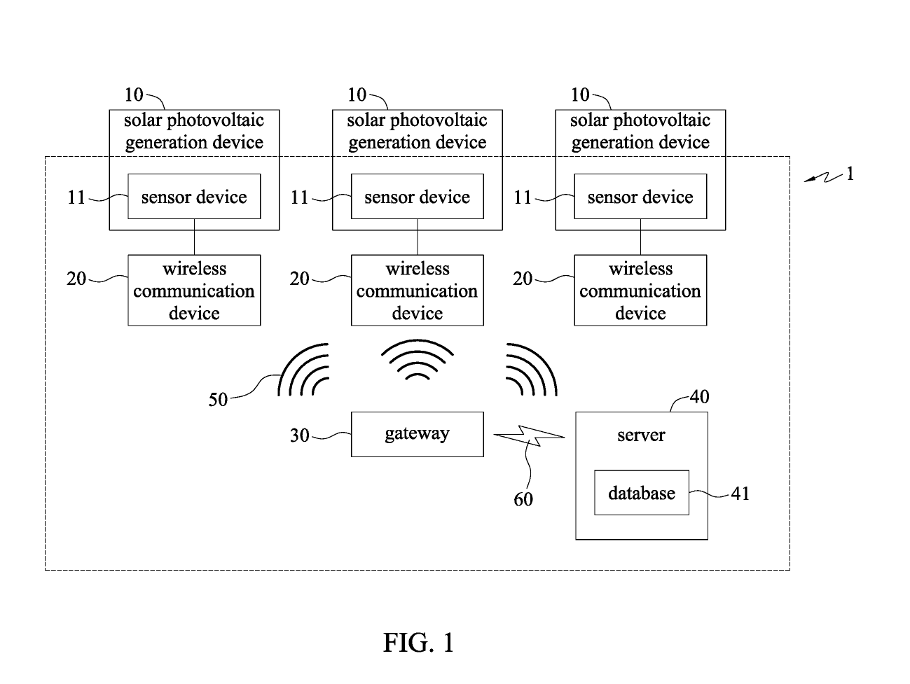

Please referring to FIG. 1, a solar photovoltaic generation monitoring system 1 is used for acquiring the solar photovoltaic data to monitor the photovoltaic generation quality. The solar photovoltaic generation monitoring system 1 comprises: a plurality of sensor devices 11, a plurality of wireless communication devices 20, a gateway 30, and a server 40.

A plurality of the sensors 11 are provided in the plurality of solar photovoltaic generation devices for acquiring electrical parameters of the plurality of solar photovoltaic generation devices and environmental parameters around the plurality of solar photovoltaic generation devices. In an embodiment, one sensor 11 or a plurality of the sensors 11 can be provided in the solar photovoltaic device 10, and further be actuated by a microcontroller, wherein the microcontroller may be a single-chip microcontroller, such as an open source Arduino Uno.

In an embodiment, a plurality of the sensors 11 may be a voltage sensor, a current sensor, a temperature sensor, a humidity sensor, a rain gauge, a wind vane, or a combination thereof. Therefore, the environmental parameters, such as temperature, humidity, rainfall, wind direction, wind speed, atmospheric pressure, illuminance, or a combination thereof can be detected, and the electrical parameters such as current and voltage value when the solar photovoltaic generation device generates electricity can be detected, but is not limit to, in second as unit. In an embodiment, the solar photovoltaic generation device 10 (i.e. the solar photovoltaic generation device to be monitored by the solar photovoltaic generation monitoring system of the present disclosure) provided with a plurality of sensor devices 11 is a polycrystalline silicon solar cells, specifically. In another embodiment, the solar photovoltaic generation device 10 may be, but is not limited to, a single crystal silicon, amorphous, CIGS (Cu, In, Ga, Se) or III-V groups compound semiconductor solar cell. In addition, the solar photovoltaic generation device 10 can also provide power for actuating the sensor devices provided in the solar photovoltaic generation monitoring system 1.

The plurality of wireless communication devices 20 are respectively connected to the plurality of sensor devices 11, so as to receive the electrical parameters and environmental parameters acquired by the sensor device 11. In an embodiment, the sensor device 11 is connected to the wireless communication device 20 via, but is not limited to, a universal asynchronous receiver/transmitter (UART).

The gateway 30 is provided within a wireless communication range corresponding to the plurality of wireless communication devices 20, for receiving the electrical parameters and the environmental parameters. In an embodiment, the gateway 30 can connect to the plurality of wireless communication devices 20 via ZigBee communication protocol, i.e., the gateway 30 can build a connection 50 of ZigBee communication protocol to the wireless communication device 20 within the wireless communication area by IEEE 802.15.4 wireless communication standard. Alternatively, a connection 50 between the gateway 30 and the wireless communication device 20 can be built via WIFI (such as IEEE 802.11 wireless standard). The present disclosure is not limited to the particular sample mentioned above. In an embodiment, an Octopusll platform is applied as wireless communication device 20, and the platform uses TI MSP430 as CPU and is equipped with a CC240 wireless transmitter chip. In addition, the platform uses a USB interface for programming and connecting. However, the present disclosure is not limited to the specific example mentioned above.

The server 40 is connected to the gateway 30 to receive electrical parameters and environmental parameters. In addition, the server 40 comprises a database 41, and the electrical parameters and environmental parameters can be stored in the database 41 of the server 40. In an embodiment, the gateway is built by Beagleboard-Xm board, and also equipped with a mobile communication routing module to connect the server 40. The mobile communication routing module may be a GSM standard industrial mobile communication routing module, so as to build a connection 60 of GSM to the server 40 by 3G or 4G wireless connection, such that the gateway 30 can transmit the electrical parameters and environmental parameters into the server 40. Furthermore, the gateway 40 also has a USB interface to connect the wireless communication device applied Octopusll platform to acquire the electrical parameters and environmental parameters.

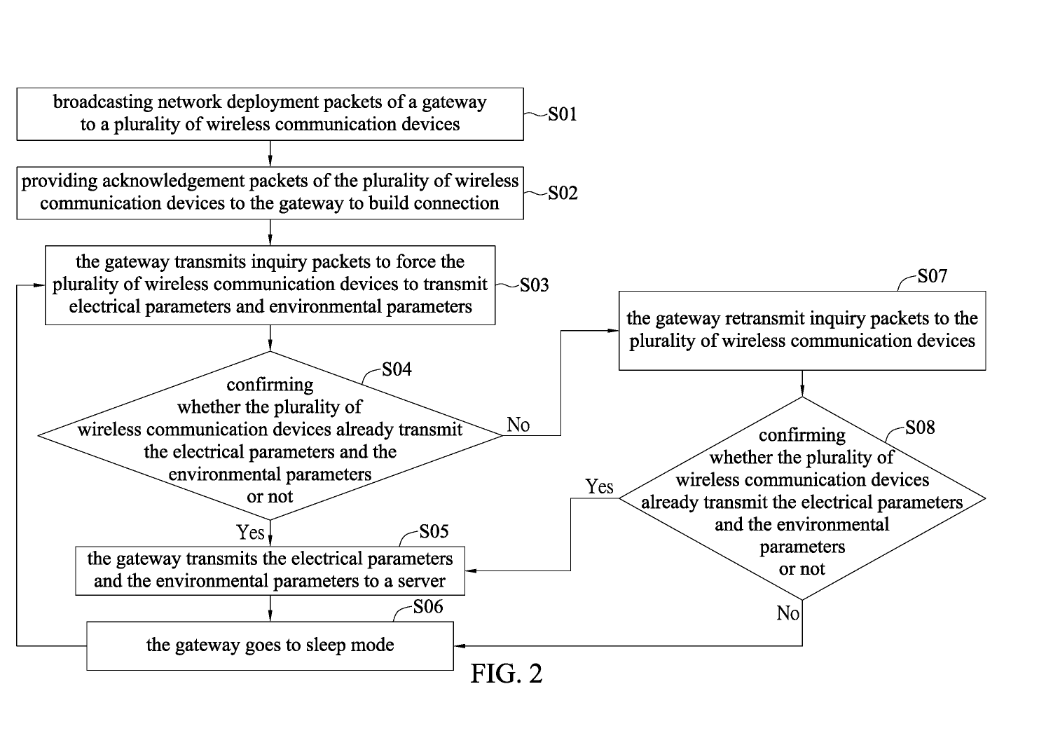

The solar photovoltaic generation monitoring system of the present disclosure can acquire the electrical parameters and environmental parameters in real time and long term. However, to directly acquire these parameters, stability of the system is also very important, so the simplified software design can avoid error come from over calculation of wireless communication device and sensor device. Therefore, utilizing centralized and a star topology network structure to build a wireless sensing network is necessary. Please referring to FIG. 2, the solar photovoltaic generation monitoring method illustrates the steps of how to build the wireless sensing network, and how to use the wireless sensing network to transmit the electrical parameters and the environmental parameters.

In step S01, broadcasting network deployment packets of the gateway to a plurality of wireless communication device, that is, the gateway broadcasts the network deployment packets to ensure whether the gateway is provided within the wireless communication range corresponding to the plurality of wireless communication devices. If so, the wireless communication device will receive the network deployment packet. It means the connection between the wireless communication device and the gateway can be built, and the gateway can determine the number of the wireless communication device received the network deployment packet. Then proceed to step S02.

In step S02, acknowledgement packets of the plurality of wireless communication devices are provided to the gateway to build connection. Specifically, the wireless communication device which received the network deployment packet will send an acknowledgement packet to the gateway. In this way, the plurality of wireless communication devices will build connections with the gateway. Then proceed to step S03.

In step S03, the gateway transmits inquiry packet to the plurality of wireless communication devices to which the gateway already built connection, so as to drive the plurality of wireless communication devices transmitting the electrical parameters while the plurality of solar photovoltaic generation devices are generating power, and the environmental parameters surrounding the plurality of solar photovoltaic generation devices to the gateway.

In an embodiment, the plurality of wireless communication devices schedule to transmit the electrical parameters and environmental parameters according to a scheduled time slot.

Next proceed to step S04. Step S04 is a check step, mainly to determine whether the plurality of wireless communication devices which already built a connection transmit the electrical parameters and environmental parameters to the gateway.

If a plurality of the wireless communication devices which already built connection do not transmit the electrical parameters and environmental parameters to the gateway, then proceeding to step S07, in which the gateway will re-transmit an inquiry packet to the plurality of wireless communication devices which does not send the parameters yet, so as to request the plurality of wireless communication devices which does not send the parameters to re-transmit the electrical parameters and environmental parameters to the gateway. Next, proceed to step S08, double check whether the plurality of wireless communication devices already transmit the electrical parameters and the environmental parameters.

In step S04 or step S08, if the plurality of wireless communication devices which have already built a connection are confirmed that the wireless communication devices already transmitted the electrical parameters and the environmental parameters, then proceeding to step S05. In step S05, the gateway will transmit the electrical parameters and the environmental parameters to a server, so as to store the electrical parameters and the environmental parameters into a database. After finishing this process, proceed to step S06. In step S06, the gateway will go to sleep mode to save the power and wait a scheduled time slot to awake the gateway again. When the gateway is awaked, the method will go back to step S03 to request the wireless communication devices to transmit the electrical parameters and the environmental parameters again.

In an embodiment of step S08, after double checking, if the plurality of wireless communication devices which does not transmit the electrical parameters and the environmental parameters, then proceed to step S06, such that the gateway will go to sleep mode directly, that is, giving up the schedule requesting for transmitting the electrical parameters and the environmental parameters.

In an embodiment, user can further analysis the electrical parameters and the environmental parameters transmitted to the database of the server by a back-end monitoring platform built by PHP and SQL.

The solar photovoltaic generation monitoring system and method thereof can solve the problems of high costs and the difficulties of building a hard wire monitoring system, and provides a stable system and monitoring technique, and it is easily to maintain and low cost. In addition, the solar photovoltaic generation monitoring system and method thereof of the present disclosure can transmit the electrical parameters and the environmental parameters acquired in each time through the scheduled time slot, to the back-end server, and users can browse the operation status and check the power generation quality of the system through an internet service in real-time.

The present disclosure has been described with exemplary embodiments to illustrate the principles, features, and efficacies of the present disclosure, but not intend to limit the implementation scope of the present disclosure. The present disclosure without departing from the spirit and scope of the premise can make various changes and modifications by a person skilled in the art. However, any equivalent change and modification accomplished according to the disclosure of the present disclosure should be considered as being covered in the scope of the present disclosure. The scope of the disclosure should be defined by the appended claims.

What is claimed is:

1. A solar photovoltaic generation monitoring system, comprising:
a plurality of sensor devices, each provided in a plurality of solar photovoltaic generation devices and configured to acquire electrical parameters of the plurality of solar photovoltaic generation devices and environmental parameters around the plurality of solar photovoltaic generation devices;
a plurality of wireless communication devices, each connected to the plurality of sensor devices and configured to receive the electrical parameters and the environmental parameters;
a gateway provided in a wireless communication range corresponding to the plurality of wireless communication devices and configured to receive the electrical parameters and the environmental parameters; and
a server connected to the gateway, and configured to receive the electrical parameters and the environmental parameters from the gateway and store the electrical parameters and the environmental parameters.

2. The solar photovoltaic generation monitoring system of claim 1, wherein the plurality of sensor devices are voltage sensors, current sensors, temperature sensors, humidity sensors, rain gauges, wind vanes or a combination thereof.

3. The solar photovoltaic generation monitoring system of claim 1, wherein the environmental parameters are temperature, humidity, rainfall, wind direction, wind speed, atmospheric pressure, illuminance or a combination thereof.

4. The solar photovoltaic generation monitoring system of claim 1, wherein the electrical parameters are current and voltage generated by the solar photovoltaic generation device.

5. The solar photovoltaic generation monitoring system of claim 1, further comprising a universal asynchronous receiver/transmitter (UART) connecting the plurality of sensor devices to the plurality of wireless communication devices.

6. The solar photovoltaic generation monitoring system of claim 1, wherein the gateway is connected to the plurality of wireless communication devices via ZigBee communication protocol or IEEE 802.11 wireless network communication standard.

7. The solar photovoltaic generation monitoring system of claim 1, wherein the gateway is connected to the server through a GSM standard industrial mobile communication routing module.

8. The solar photovoltaic generation monitoring system of claim 1, wherein the plurality of solar photovoltaic generation devices are polycrystalline silicon, single crystal silicon, amorphous, CIGS (Cu, In, Ga, Se) or III-V group compounds semiconductor solar cells.

9. A method for monitoring solar photovoltaic generation, comprising:
broadcasting network deployment packets to a plurality of wireless communication devices to ensure whether a gateway is provided within a wireless communication range corresponding to the plurality of wireless communication devices and ensure the number of the wireless communication devices connecting to the gateway;
providing to the gateway an acknowledgement packet of the plurality of wireless communication devices receiving the network deployment packet to build connection between the gateway and the plurality of wireless communication devices;
transmitting, by the gateway, inquiry packets to the plurality of wireless communication devices with the built connection for the plurality of wireless communication devices to transmit electrical parameters of a plurality of solar photovoltaic generation devices and environmental parameters around the plurality of solar photovoltaic generation devices to the gateway; and
transmitting, by the gateway, the electrical parameters and the environmental parameters to a server, and storing the electrical parameters and the environmental parameters in the server.

10. The method for monitoring solar photovoltaic generation of claim 9, further comprising, after transmitting the electrical parameters and the environmental parameters to the gateway, checking whether the plurality of wireless communication devices with the built connection transmit the electrical parameters and the environmental parameters.

11. The method for monitoring solar photovoltaic generation of claim 10, wherein the plurality of wireless communication devices with the built connection does not transmit the electrical parameters and the environmental parameters, and the gateway re-transmits the inquiry packets to the plurality of wireless communication devices without the transmitted electrical parameters and the transmitted environmental parameters to re-transmit the electrical parameters and the environmental parameters to the gateway.

12. The method for monitoring solar photovoltaic generation of claim 10, wherein the plurality of wireless communication devices with the built connection transmit the electrical parameters and the environmental parameters, and the gateway transmits the electrical parameters and the environmental parameters to the server to have the electrical parameters and environmental parameters stored in the server.

13. The method for monitoring solar photovoltaic generation of claim 10, wherein the plurality of wireless communication devices transmit the electrical parameters and the environmental parameters according to a scheduled time slot.

14. The method for monitoring solar photovoltaic generation of claim 9, further comprising acquiring the electrical parameters and the environmental parameters by a plurality of sensor devices.

15. The method for monitoring solar photovoltaic generation of claim 14, wherein the plurality of sensor devices connect to the plurality of wireless communication devices through a universal asynchronous receiver/transmitter (UART).

16. The method for monitoring solar photovoltaic generation of claim 14, wherein the plurality of sensor devices are voltage sensors, current sensors, temperature sensors, humidity sensors, rain gauges, wind vanes or a combination thereof.

17. The method for monitoring solar photovoltaic generation of claim 9, wherein the gateway is connected to the plurality of wireless communication devices via ZigBee communication protocol or IEEE 802.11 wireless network communication standard.

18. The method for monitoring solar photovoltaic generation of claim 9, wherein the gateway is connected to the server through a GSM standard industrial mobile communication routing module.

19. The method for monitoring solar photovoltaic generation of claim 9, wherein the plurality of solar photovoltaic generation devices are polycrystalline silicon, single crystal silicon, amorphous, CIGS (Cu, In, Ga, Se) or III-V group compounds semiconductor solar cells.

20. The method for monitoring solar photovoltaic generation of claim 9, wherein the environmental parameters are temperature, humidity, rainfall, wind direction, wind speed, atmospheric pressure, illuminance or a combination thereof, and the electrical parameters are current and voltage generated by the solar photovoltaic generation device.
